(19) United States
(12) Patent Application Publication
(10) Pub. No.: US 2019/0202685 A1
(43) Pub. Date: Jul. 4, 2019

(54) CHIP PACKAGE AND CHIP PACKAGING METHOD

(71) Applicant: China Wafer Level CSP Co., Ltd., Suzhou (CN)

(72) Inventor: Zhiqi Wang, Suzhou (CN)

(73) Assignee: China Wafer Level CSP Co., Ltd., Suzhou (CN)

(21) Appl. No.: 16/211,090

(22) Filed: Dec. 5, 2018

(30) Foreign Application Priority Data
Dec. 29, 2017 (CN) 201711469223.2
Dec. 29, 2017 (CN) 201721922151.8

(51) Int. Cl. B81B 7/00; H01L 23/00; B81B 7/02; B81C 1/00

(52) U.S. Cl. CPC B81B 7/0077; H01L 24/17; H01L 24/09; H01L 24/73; B81B 7/02; B81B 2203/0353; H01L 2924/1433; B81B 2207/09; B81B 2207/115; B81B 2203/0315; B81C 1/00333

(57) ABSTRACT

A chip package and a chip packaging method are provided. A MEMS chip and an ASIC chip are packaged by using a packaged circuit board. The packaged circuit board is provided with a receiving hole. The MEMS chip and the ASIC chip are respectively attached to two surfaces of the packaged circuit board and cover receiving hole. The MEMS chip and the ASIC chip are connected with each other via the packaged circuit board, and are connected to an external circuit via the packaged circuit board, thereby facilitating a circuit interconnection between the package and an electronic component.

The present application claims priorities to Chinese Patent Application No. 201711469223.2, titled “CHIP PACKAGE AND CHIP PACKAGING METHOD”, filed on Dec. 29, 2017 with the State Intellectual Property Office of People's Republic of China, and Chinese Patent Application No. 201721922151.8, titled “CHIP PACKAGE”, filed on Dec. 29, 2017 with the State Intellectual Property Office of People's Republic of China, both of which are incorporated herein by reference in their entireties.

### FIELD

The present disclosure relates to the field of chip packaging technology, and in particular to a chip package and a chip packaging method.

### BACKGROUND

The micro-electro-mechanical systems (MEMS) are developed by combining the microelectronic technology and the mechanical engineering technology. The MEMS is operated in a micrometer order. In the development of the MEMS, it is required to consider the mutual interaction of multiple physical fields. Compared with a conventional mechanical device, the MEMS has a smaller size, which is not more than one centimeter or may even be several micrometers, and the thickness the MEMS is also smaller. In the integrated circuit field, the application specific integrated circuit (ASIC) is designed for a specific purpose, which has an advantage of meeting a specific requirement of a user. Compared with a general-purpose integrated circuit, the ASIC has advantages such as a smaller size, a lower power consumption, an improved reliability, an improved performance, an improved security, and a reduced cost when produced in bathes.

The MEMS chips and the ASIC chips having high performance may be produced in bathes with a low cost by using mature technologies and processes for integrated circuits. Due to the package formed by integrally packaging the MEMS chip and the ASIC chip, a brand-new technical field and industry are developed. Devices manufactured based on the package, such as a micro-sensor, a micro-actuator, a micro-component, a micro mechanical optical device, a vacuum micro-electronic device and a power electronic device, have broad application prospects in almost all fields involved by people, such as aviation, aerospace, automotive, biomedical, environmental monitoring and military.

In the conventional technology, in a common package for the MEMS chip and the ASIC chip, the MEMS chip and the ASIC chip are attached to each other by using an adhesive layer or by welding, thus a circuit interconnection between the package and an electronic component is not facilitated.

### SUMMARY

In order to solve the above problem, a chip package and a chip packaging method are provided in the present disclosure. An MEMS chip and an ASIC chip are respectively attached to two surfaces of a packaged circuit board having a receiving hole, and the MEMS chip and the ASIC chip are connected with each other via the packaged circuit board and are connected to an external circuit via the packaged circuit board, thereby facilitating the circuit interconnection between the package and an electronic component.

The following technical solutions are provided in the present disclosure.

A chip package is provided, which includes a packaged circuit board, an ASIC chip, and an MEMS chip. The packaged circuit board is provided with a receiving hole. The ASIC chip is attached to one surface of the packaged circuit board and covers the receiving hole. The MEMS chip is attached to the other surface of the packaged circuit board and covers the receiving hole. The MEMS chip includes opposing front and back surfaces. The front surface of the MEMS chip is provided with a first function unit. The front surface of the MEMS chip is disposed facing the receiving hole. The first function unit is disposed facing the receiving hole. The packaged circuit board is provided with a wiring circuit and first connection terminals connected to the wiring circuit. Each of the first connection terminals is connected with an external circuit. The ASIC chip and the MEMS chip are connected to the wiring circuit.

In an embodiment, in the chip package, the MEMS chip further includes a cover covering the first function unit. The cover is provided with a cavity, and an opening of the cavity is disposed facing the first function unit. The cover is located in the receiving hole.

In an embodiment, in the chip package, there is a gap between a top surface of the cover and the ASIC chip.

In an embodiment, in the chip package, a top surface of the cover does not extend beyond a surface of the packaged circuit board to which the ASIC chip is attached, and a bottom surface of the cover is exposed beyond a surface of the packaged circuit board to which the MEMS chip is attached.

In an embodiment, in the chip package, the packaged circuit board includes opposing first and second surfaces. The ASIC chip is attached to the first surface, and the MEMS chip is attached to the second surface.

In an embodiment, in the chip package, there is a gap between the ASIC chip and the MEMS chip.

In an embodiment, in the chip package, the first surface is provided with first contact pads. The second surface is provided with second contact pads. The first contact pads and the second contact pads are connected to the wiring circuit. The first connection terminals are located on the second surface. A surface of the ASIC chip facing the packaged circuit board is provided with second connection terminals, and each of the second connection terminals is connected to one first contact pad. The front surface of the MEMS chip is provided with third contact pads connected to the first function unit, and each of the third contact pads is connected to one second contact pad.

In an embodiment, in the chip package, the ASIC chip is provided with multiple second connection terminals, and the packaged circuit board is provided with multiple first contact pads connected to the second connection terminals in a one-to-one correspondence. The MEMS chip is provided with multiple third contact pads, and the packaged circuit board is provided with multiple second contact pads connected to the third contact pads in a one-to-one correspondence.

In an embodiment, in the chip package, the wiring circuit includes a first wiring circuit, a second wiring circuit, and a third wiring circuit. The first wiring circuit is configured to connect the first contact pad to the second contact pad. The second wiring circuit is configured to connect the first contact pad to the second contact pad, and connect the first contact pad and the second contact pad together to a corresponding first connection terminal. The third wiring circuit is configured to connect the first contact pad or the second contact pad to a corresponding first connection terminal.

In an embodiment, in the chip package, the ASIC chip includes opposing front and back surfaces. The back surface of the ASIC chip is disposed facing the first surface. The front surface of the ASIC chip is provided with a second function unit and fourth contact pads connected to the second function unit. The back surface of the ASIC chip is provided with the second connection terminals, and each of the second connection terminals is connected to one fourth contact pad.

In an embodiment, in the chip package, the back surface of the ASIC chip is provided with through holes, and each of the through holes exposes one fourth contact pad. The back surface of the ASIC chip is provided with an insulation layer, and the insulation layer covers a sidewall of each of the through holes and extends outside the through hole. A surface of the insulation layer is covered with a rewiring layer, and the rewiring layer is connected to the fourth contact pad at the bottom of each of the through holes and extends outside the through hole. A surface of the rewiring layer is covered with a solder mask, the solder mask has openings at a region outside the through holes for exposing the rewiring layer, and each of the second connection terminals is disposed in one opening, and the second connection terminal is connected to the fourth contact pad via the rewiring layer.

In an embodiment, in the chip package, the second connection terminal is a solder bump.

In an embodiment, in the chip package, the first connection terminal is a solder bump.

A chip packaging method is further provided in the present disclosure. The chip packaging method includes:

providing a to-be-cut substrate, where the to-be-cut substrate includes multiple chip attaching regions, a cutting trench is formed between adjacent chip attaching regions, each of the chip attaching regions is provided with a wiring circuit and a receiving hole penetrating the to-be-cut substrate;

attaching an application specific integrated circuit (ASIC) chip to one surface of the chip attaching region and attaching a micro-electro-mechanical system (MEMS) chip to the other surface of the chip attaching region, where the ASIC chip and the MEMS chip cover the receiving hole, the MEMS chip includes opposing front and back surfaces, the front surface of the MEMS chip is provided with a first function unit, the front surface of the MEMS chip is disposed facing the receiving hole, the first function unit is disposed facing the receiving hole, and the ASIC chip and the MEMS chip are connected to the wiring circuit;

forming first connection terminals connected to the wiring circuit on a surface of the chip attaching region to which the MEMS chip is attached, where each of the first connection terminals is connected to an external circuit; and

cutting the to-be-cut substrate along the cutting trenches to form multiple packaged circuit boards, where each of the packaged circuit boards includes one chip attaching region, and each of the packaged circuit boards is attached with one ASIC chip and one MEMS chip.

In an embodiment, in the chip packaging method, the MEMS chip further includes a cover covering the first function unit. The cover is provided with a cavity. An opening of the cavity is disposed facing the first function unit. The cover is located in the receiving hole.

In an embodiment, in the chip packaging method, there is a gap between a top surface of the cover and the ASIC chip.

In an embodiment, in the chip packaging method, a top surface of the cover does extend beyond a surface of the packaged circuit board to which the ASIC chip is attached. A bottom surface of the cover is exposed beyond a surface of the packaged circuit board to which the MEMS chip is attached.

In an embodiment, in the chip packaging method, the packaged circuit board includes opposing first and second surfaces. The ASIC chip is attached to the first surface, and the MEMS chip is attached to the second surface.

In an embodiment, in the chip packaging method, there is a gap between the ASIC chip and the MEMS chip.

In an embodiment, in the chip packaging method, the first surface is provided with first contact pads. The second surface is provided with second contact pads. The first contact pads and the second contact pads are connected to the wiring circuit. The first connection terminals are located on the second surface. A surface of the ASIC chip facing the packaged circuit board is provided with second connection terminals. The front surface of the MEMS chip is provided with third contact pads connected to the first function unit. The attaching the ASIC chip to one surface of the chip attaching region and attaching the MEMS chip on the other surface of the chip attaching region includes: connecting the second connection terminal to the first contact pad, and connecting the third contact pad to the second contact pad.

In an embodiment, in the chip packaging method, the ASIC chip is provided with multiple second connection terminals, and the packaged circuit board is provided with multiple first contact pads connected to the second connection terminals in a one-to-one correspondence. The MEMS chip is provided with multiple third contact pads, and the packaged circuit board is provided with multiple second contact pads connected to the third contact pads in a one-to-one correspondence.

In an embodiment, in the chip packaging method, the wiring circuit includes a first wiring circuit, a second wiring circuit and a third wiring circuit. The first wiring circuit configured to connect the first contact pad to the second contact pad. The second wiring circuit is configured to connect the first contact pad to the second contact pad, and connect the first contact pad and the second contact pad together to a corresponding first connection terminal. The third wiring circuit is configured to connect the first contact pad or the second contact pad to a corresponding first connection terminal.

In an embodiment, in the chip packaging method, the ASIC chip includes opposing front and back surfaces. The back surface of the ASIC chip is disposed facing the first surface. The front surface of the ASIC chip is provided with a second function unit and fourth contact pads connected to the second function unit. The back surface of the ASIC chip is provided with the second connection terminals. Each of the second connection terminals is connected to one fourth contact pad. The connecting the second connection terminal to the first contact pad includes: connecting the second connection terminal to the first contact pad by a welding process.

In an embodiment, in the chip packaging method, the back surface of the ASIC chip is provided with through holes, and each of the through holes exposes one fourth contact pad. The back surface of the ASIC chip is provided with an insulation layer, and the insulation layer covers a sidewall of each of the through holes and extends outside the through hole. A surface of the insulation layer is covered with a rewiring layer, and the rewiring layer is connected to the fourth contact pad at the bottom of each of the through holes and extends outside the through hole. A surface of the rewiring layer is covered with a solder mask. The solder mask is provided with openings at a region outside the through holes for exposing the rewiring layer. Each of the second connection terminals is disposed in one opening. The second connection terminal is connected to the fourth contact pad via the rewiring layer.

In an embodiment, in the chip packaging method, the second connection terminal is a solder bump.

In an embodiment, in the chip packaging method, the first connection terminal is a solder bump.

It can be seen from the above description that, in the chip package and the chip packaging method according to technical solutions of the present disclosure, the MEMS chip and the ASIC chip are packaged by using a packaged circuit board. The packaged circuit board is provided with a receiving hole. The MEMS chip and the ASIC chip are respectively attached to two surfaces of the packaged circuit board and cover the receiving hole. The MEMS chip and the ASIC chip are connected with each other via the packaged circuit board and are connected to an external circuit via the packaged circuit board, thereby facilitating a circuit interconnection between the package and an electronic component.

### BRIEF DESCRIPTION OF THE DRAWINGS

In order to more clearly illustrating technical solutions in embodiments of the present disclosure or in the conventional technology, the drawings used to describe the embodiments or the conventional technology are briefly described hereinafter. It is apparent that the drawings in the following description show only some embodiments of the present disclosure, and other drawings may be obtained by those skilled in the art based on the drawings without any creative efforts.

FIG. 1 is a schematic structural diagram of a conventional package for a MEMS chip and an ASIC chip;

FIG. 2 is a schematic structural diagram of another conventional package for a MEMS chip and an ASIC chip;

FIG. 3 is a schematic structural diagram of a chip package according to an embodiment of the present disclosure:

FIG. 4 is a schematic structural diagram of a MEMS chip in the chip package shown in FIG. 3;

FIG. 5 is a schematic structural diagram of an ASIC chip in the chip package shown in FIG. 3;

FIGS. 6 to 9 are schematic diagrams showing a flowchart of a chip packaging method according to an embodiment of the present disclosure;

FIGS. 10 to 13 are schematic diagrams showing a flowchart of a method for manufacturing a MEMS chip according to an embodiment of the present disclosure; and

FIGS. 14 to 21 are schematic diagrams showing a flowchart of a method for manufacturing an ASIC chip according to an embodiment of the present disclosure.

### DETAILED DESCRIPTION OF EMBODIMENTS

Technical solutions of embodiments of the present disclosure are clearly and completely described hereinafter in conjunction with the drawings of the embodiments of the present disclosure. It is apparent that the embodiments described in the following are only some embodiments of the present disclosure, rather than all embodiments. Any other embodiments obtained by those skilled in the art based on the embodiments in the present disclosure without any creative efforts should fall within the protection scope of the present disclosure.

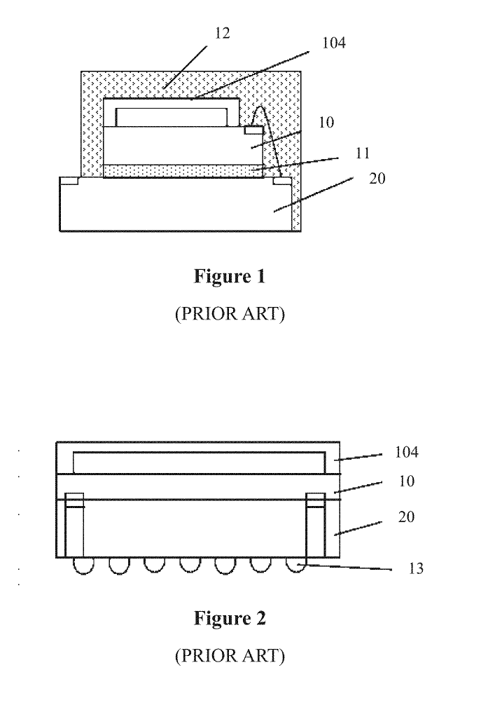

Reference is made to FIG. 1, which is a schematic structural diagram of a conventional package for a MEMS chip and an ASIC chip. A MEMS chip 10 and an ASIC chip 20 are attached by using an adhesive layer 11. A front surface of the MEMS chip 10 is covered with a cover 104. The MEMS chip 10 and the ASIC chip 20 are connected with each other by a wire. In this package, it is required to attach the MEMS chip 10 and the wire by a thick injection molding structure 12, and expose contact pads to be connected to an external circuit and disposed on a surface of the ASIC chip 20 from the injection molding structure 12. The contact pad is connected to the external circuit by a wire. In this implementation, the MEMS chip and the ASIC chip are connected with each other by a wire, the MEMS chip and the ASIC chip are connected to the external circuit by a wire, and the packaging is performed by an injection molding process, resulting in a large size, a poor connection stability of wires, and a high manufacturing cost.

Reference is made to FIG. 2, which is a schematic structural diagram of another conventional package for a MEMS chip and an ASIC chip. The MEMS chip 10 and an ASIC chip 20 are attached by directly welding at solder terminals on a back surface of the MEMS chip 10 and a front surface of the ASIC chip 20. Similarly, the front surface of the MEMS chip 10 is provided with a cover 104. The back surface of the ASIC chip 20 is provided with connection terminals 13 to be connected to an external circuit. The connection terminal 13 is connected to the solder terminal on the front surface of the ASIC chip 20 via a through hole. In this implementation, it is required that the MEMS chip 10 and the ASIC chip 20 have the same size. With an increased size of the MEMS chip 10, the integration of the package is low, and the cost is high, which is not conforming to the existing development trend of a decreased size of the MEMS chip 10. In addition, in this implementation, it is required to electrical couple the MEMS chip 10 and the ASIC chip 20 in a flip manner, and form the connection terminals 13 on the back surface of the ASIC chip 20 by a TSV process, to facilitate the connection to the external circuit, thereby resulting in a complicated process and a high cost.

In order to solve the above problems, a package for a MEMS chip and an ASIC chip is provided according to an embodiment of the present disclosure. In the package, the MEMS chip and the ASIC chip are packaged by using a packaged circuit board. The packaged circuit board is provided with a receiving hole, the MEMS chip and the ASIC chip are respectively attached to two surfaces of the packaged circuit board and cover the receiving hole. The MEMS chip and the ASIC chip are connected with each other via the packaged circuit board and are connected to an external circuit via the packaged circuit board, thereby facilitating a circuit interconnection between the package and an electronic component. With the package according to the embodiment of the present disclosure, the manufacturing process is simple, the manufacturing cost is low, and the integration is high.

In order to make the above objects, features and advantages of the present disclosure more apparent and easier to be understood, the present disclosure is illustrated in detail in conjunction with the drawings and specific embodiments hereinafter.

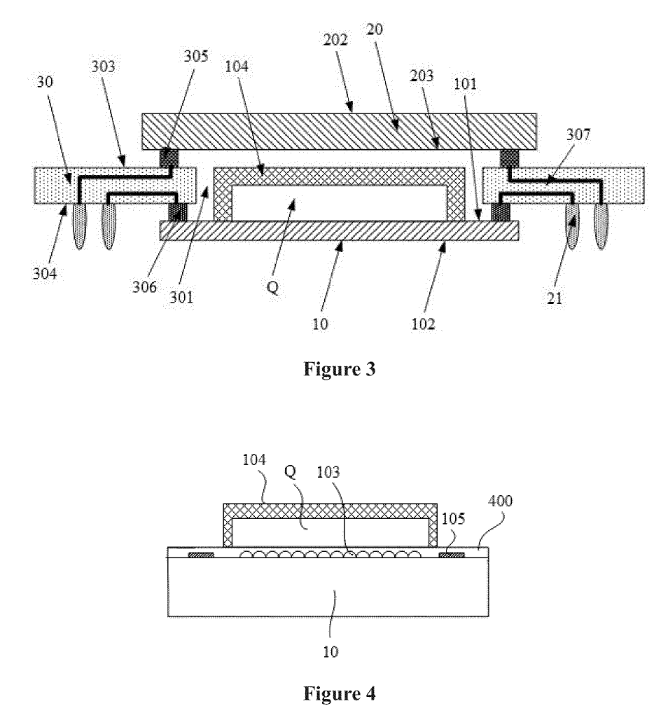

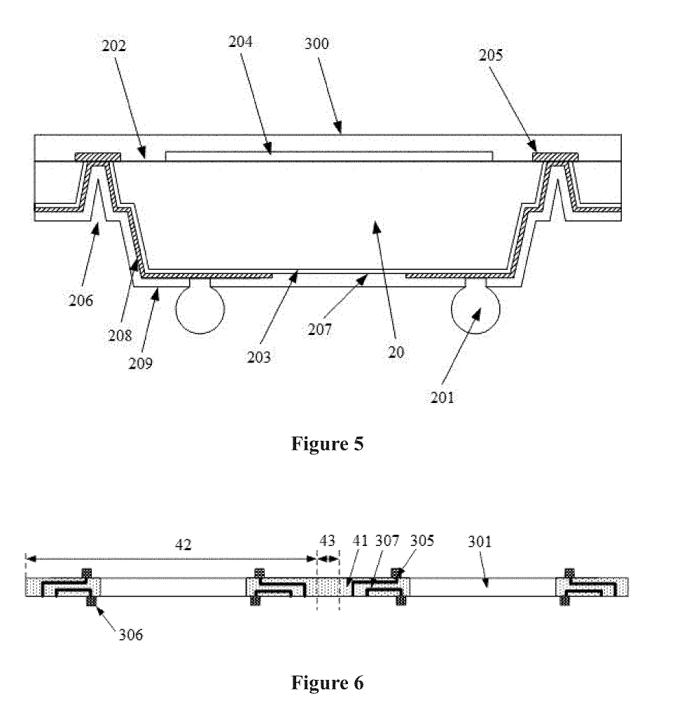

Reference is made to FIGS. 3 to 5, FIG. 3 is a schematic structural diagram of a chip package according to an embodiment of the present disclosure, FIG. 4 is a schematic structural diagram of a MEMS chip in the chip package shown in FIG. 3, and FIG. 5 is a schematic structural diagram of an ASIC chip in the chip package shown in FIG. 3. The chip package includes a packaged circuit board 30, an ASIC chip 20 and a MEMS chip 10. The packaged circuit board 30 is provided with a receiving hole 301. The ASIC chip 20 is attached to one surface of the packaged circuit board 30 and covers the receiving hole 301. The MEMS chip 10 is attached to the other surface of the packaged circuit board 30 and covers the receiving hole 301.

The MEMS chip 10 includes opposing front surface 101 and back surface 102. The front surface 101 of the MEMS chip 10 is provided with a first function unit 103. The front surface 101 of the MEMS chip 10 is disposed facing the receiving hole 301. The first function unit 103 is disposed facing the receiving hole 301.

The packaged circuit board 30 is provided with a wiring circuit 307 and first connection terminals 21 connected to the wiring circuit 307. The first connection terminal 21 is connected to an external circuit. The ASIC chip 20 and the MEMS chip 10 are connected to the wiring circuit 307.

In an embodiment, the MEMS chip 10 further includes a cover 104 covering the first function unit 103. The cover 104 is provided with a cavity Q. and an opening of the cavity Q is disposed facing the first function unit 103. The cover 104 is located in the receiving hole 301. The cover 104 is accommodated in the receiving hole 301, such that not only the first function unit 103 is protected, but also the thickness of the package is not increased. The front surface 101 of the MEMS chip 10 is covered with a protection layer 400. The first function unit 103 is covered by the protection layer 400, such that not only the first function unit 103 is protected, but also the smoothness of the front surface 101 of the MEMS chip 10 is ensured, thereby facilitating the lamination of the front surface of the MEMS chip 10 to the packaged circuit board 30.

There is a gap between a top surface of the cover 104 and the ASIC chip 20, to facilitate that the ASIC chip 20 and the MEMS chip 10 are respectively attached to two surfaces of the packaged circuit board 30. The top surface of the cover 104 does not extend beyond a surface of the packaged circuit board 30 to which the ASIC chip 20 is attached, to avoid a stress from being generated between the top surface of the cover 104 and the ASIC chip 20 when the top surface of the cover 104 is in contact with the ASIC chip 20. Further, a bottom surface of the cover 104 is exposed beyond a surface of the packaged circuit board 30 to which the MEMS chip 10 is attached, to facilitate the attach of the MEMS chip 10 to the packaged circuit board 30.

The packaged circuit board 30 includes opposing first surface 303 and second surface 304. The ASIC chip 20 is attached to the first surface 303, and the MEMS chip 10 is attached to the second surface 304. In a case where the ASIC chip 20 and the MEMS chip 10 are respectively attached to two surfaces of the packaged circuit board 30, there is a gap between the ASIC chip 20 and the MEMS chip 10.

The first surface 303 is provided with first contact pads 305. The second surface 304 is provided with second contact pads 306. The first contact pads 305 and the second contact pads 306 are connected to the wiring circuit 307. The first connection terminals 21 are located on the second surface 304. A surface of the ASIC chip 20 facing the packaged circuit board 30 is provided with second connection terminals 201. Each of the second connection terminals 201 is connected to one first contact pad 305. The front surface 101 of the MEMS chip 10 is provided with third contact pads 105 connected to the first function unit 103. Each of the third contact pads 105 is connected to one second contact pad 306.

The ASIC chip 20 is provided with multiple second connection terminals 201, and the packaged circuit board 30 is provided with multiple first contact pads 305 connected to the second connection terminals 201 in a one-to-one correspondence. The MEMS chip 10 is provided with multiple third contact pads 105, and the packaged circuit board 30 is provided with multiple second contact pads 306 connected to the third contact pads 105 in a one-to-one correspondence.

In the packaged circuit board, the wiring circuit 307 includes a first wiring circuit, a second wiring circuit and a third wiring circuit. The first wiring circuit is configured to connect the first contact pad 305 to the second contact pad 306. The second wiring circuit is configured to connect the first contact pad 305 to the second contact pad 306, and connect the first contact pad 305 and the second contact pad 306 together to a corresponding first connection terminal 21. The third wiring circuit is configured to connect the first contact pad 305 or the second contact pad 306 to a corresponding first connection terminal 21.

The ASIC chip 20 includes opposing front surface 202 and back surface 203. The back surface 203 of the ASIC chip 20 is disposed facing the first surface 303. The front surface 202 of the ASIC chip 20 is provided with a second function unit 204 and fourth contact pads 205 connected to the second function unit 204. The back surface 203 of the ASIC chip 20 is provided with the second connection terminals 201. Each of the second connection terminals 201 is connected to one fourth contact pad 205.

The back surface 203 of the ASIC chip 20 is provided with through holes 206. Each of the through holes 206 exposes one fourth contact pad 205. The back surface 203 of the ASIC chip 20 is provided with an insulation layer 207. The insulation layer 207 covers a sidewall of each of the through holes 206 and extends outside the through hole 206. A surface of the insulation layer 207 is covered with a rewiring layer 208. The rewiring layer 208 is connected to the fourth contact pad 205 at the bottom of each of the through holes 206 and extends outside the through hole 206. A surface of the rewiring layer 208 is covered with a solder mask 209. The solder mask 209 is provided with openings at a region outside the through holes 206, to expose the rewiring layer 208. Each of the second connection terminals 201 is disposed in one opening, and the second connection terminal 201 is connected to the fourth contact pad 205 via the rewiring layer 208. In an embodiment, the front surface 202 of the ASIC chip 20 is covered with a protection layer 300. The second function unit 204 and the fourth contact pads 205 are covered by the protection layer 300, such that not only the second function unit 202 and the fourth contact pads 205 are protected, but also the smoothness of the surface of the ASIC chip 20 is ensured, thereby facilitating the lamination of the surface of the ASIC chip 20 to another structural component.

In the package according to the embodiment of the present disclosure, the second connection terminal 201 is a solder bump, and the first connection terminal 21 is a solder bump. In the embodiment of the present disclosure, the solder bump may be a solder ball or a metal bump.

The front surface 101 of the MEMS chip 10 is provided with multiple third contact pads 105 connected to the first function unit 103, and the second surface 304 of the packaged circuit board 30 is provided with the multiple second contact pads 306 to be connected to the third contact pads 105 in a one-to-one correspondence. The front surface of the ASIC chip 20 is provided with multiple fourth contact pads 205 connected to the second function unit 204, and the first surface 303 of the packaged circuit board 30 is provided with the multiple first contact pads 305 to be connected to the fourth contact pads 205 in a one-to-one correspondence. Each of some of the first contact pads 305 and/or the second contact pads 306 may be connected to a corresponding first connection terminal 21 via the third wiring circuit. Each of some of the first contact pads 305 may be connected to a corresponding second contact pad 306 via the first wiring circuit. Each of some the first contact pads 305 may be connected to a corresponding second contact pad 306 and then to a corresponding first connection terminal 21 together with the second contact pad 306 via the second wiring circuit.

In an embodiment, the first surface 303 of the packaged circuit board 30 may further be provided with third connection terminals (which are not shown in the drawings) connected to the wiring circuit 307. The third connection terminal is connected to an external element (which is not shown in the drawings). The external element includes one or more of a resistive element, a capacitive element, an inductive element and a memory element. In the package according to the embodiment of the present disclosure, the packaged circuit board 30 may be connected to the external element. The packaged circuit board between the MEMS chip 10 and the ASIC chip 20 may further be configured to integrate with the external element, such that the thickness of the package is not increased, and the integration is improved.

It can be seen from the above description that, in the package according to the embodiment of the present disclosure, the MEMS chip 10 and the ASIC chip 20 are packaged by using the packaged circuit board 30. The packaged circuit board 30 is provided with the receiving hole 301. The MEMS chip 10 and the ASIC chip 20 are respectively attached to two surfaces of the packaged circuit board 30 and cover the receiving hole 301. The MEMS chip 10 and the ASIC chip 20 are connected with each other via the packaged circuit board 30 and are connected to an external circuit via the packaged circuit board 30, thereby facilitating a circuit interconnection between the package and an electronic component. With the package according to the embodiment of the present disclosure, the manufacturing process is simple, the manufacturing cost is low, and the integration is high.

Based on the above embodiment, a chip packaging method for manufacturing the above package is further provided according to another embodiment of the present disclosure. The chip packaging method is as shown in FIGS. 6 to 9, which are schematic diagrams showing a flowchart of a chip packaging method according to an embodiment of the present disclosure. The chip packaging method includes the following steps S11 to S14.

In step S11, as shown in FIG. 6, a to-be-cut substrate 41 is provided.

The to-be-cut substrate 41 includes multiple chip attaching regions 42. A cutting trench 43 is disposed between adjacent chip attaching regions 42. Each of the chip attaching regions 42 is provided with a wiring circuit 307 and a receiving hole 301 penetrating the to-be-cut substrate 41.

The to-be-cut substrate 41 is used to form the packaged circuit board 30 described above. Each of the chip attaching regions 42 corresponds to one packaged circuit board 30 for forming the package.

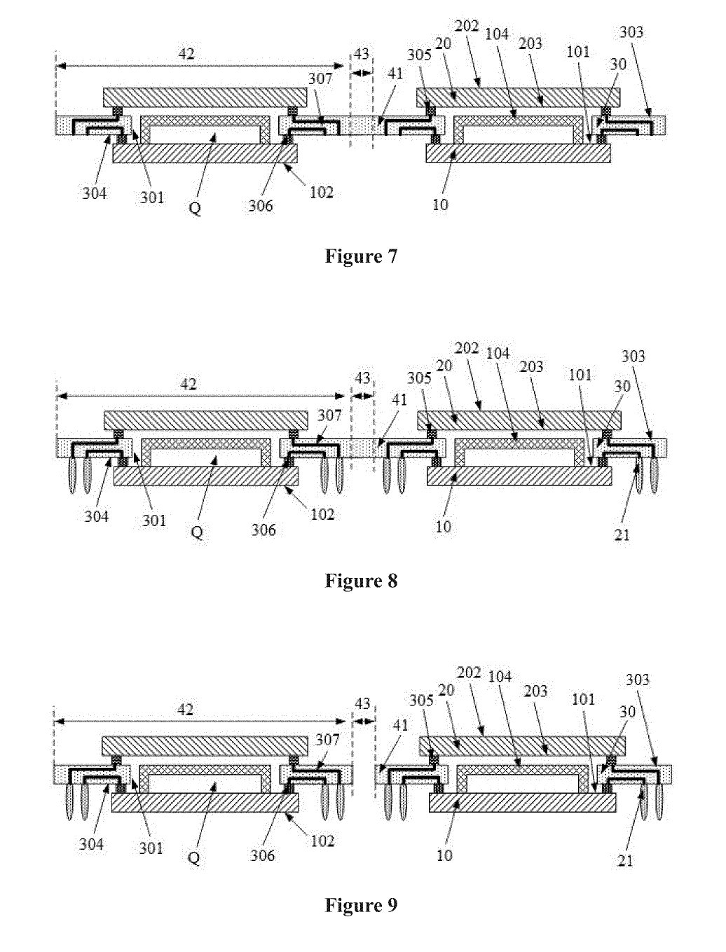

In step S12, as shown in FIG. 7, an ASIC chip 20 is attached to one surface of the chip attaching region 42, and a MEMS chip 10 is attached to the other surface of the chip attaching region. The sequence in which the two chips are attached may be determined according to actual needs, which is not limited in the embodiment of the present disclosure.

The ASIC chip 20 and the MEMS chip 10 cover the receiving hole 301.

As shown in FIG. 4, the MEMS chip 10 includes opposing front surface 101 and back surface 102. The front surface 101 of the MEMS chip 10 is provided with a first function unit 103. The front surface 101 of the MEMS chip 10 is disposed facing the receiving hole 301, and the first function unit 103 is disposed facing the receiving hole 301. The ASIC chip 20 and the MEMS chip 10 are connected to the wiring circuit 307.

In an embodiment, the MEMS chip 10 further includes a cover 104 covering the first function unit 103. The cover 104 is provided with a cavity Q, and an opening of the cavity Q is disposed facing the first function unit 103. The cover 104 is located in the receiving hole 301. There is a gap between a top surface of the cover 104 and the ASIC chip 20.

In step S13, as shown in FIG. 8, a surface of the chip attaching region 42 attached with the MEMS chip 10 is provided with first connection terminals 21 connected to the wiring circuit 307. The first connection terminal 21 is connected to an external circuit.

In step S14, as shown in FIG. 9, the to-be-cut substrate 41 is cut along the cutting trenches 43 to form multiple packaged circuit boards 30. Each of the packaged circuit boards 30 includes one chip attaching region 42, and each of the packaged circuit boards 30 is attached with one ASIC chip 20 and one MEMS chip 10.

In an embodiment, the top surface of the cover 104 does extend beyond a surface of the packaged circuit board 30 to which the ASIC chip 20 is attached. A bottom surface of the cover 104 is exposed beyond a surface of the packaged circuit board 30 to which the MEMS chip 10 is attached.

In an embodiment, the packaged circuit board 30 includes opposing first surface 303 and second surface 304. The ASIC chip 20 is attached to the first surface 303, and the MEMS chip 10 is attached to the second surface 304. There is a gap between the ASIC chip 20 and the MEMS chip 10.

The first surface 303 is provided with first contact pads 305, and the second surface 304 is provided with second contact pads 306. The first contact pads 305 and the second contact pads 306 are connected to the wiring circuit 307. The first connection terminals 21 are located on the second surface 304. A surface of the ASIC chip 20 facing the packaged circuit board 30 is provided with second connection terminals 201. The front surface 101 of the MEMS chip 10 is provided with third contact pads 105 connected to the first function unit 103. The attaching the ASIC chip 20 to one surface of the chip attaching region 42 and attaching the MEMS chip 10 to the other surface of the chip attaching region 42 includes: connecting the second connection terminal 201 to the first contact pad 305, and connecting the third contact pad 105 to the second contact pad 306.

The chip packaging method further includes: before cutting the to-be-cut substrate 41, attaching an external element to the surface of the chip attaching region 42 to which the ASIC chip 20 is attached. The surface of the chip attaching region 42 to which the ASIC chip 20 is attached is provided with third connection terminals connected to the wiring circuit 307, for attaching the external element.

The ASIC chip 20 is provided with multiple second connection terminals 201, and the packaged circuit board 30 is provided with multiple first contact pads 305 connected to the second connection terminals 201 in a one-to-one correspondence. The MEMS chip 10 is provided with multiple third contact pads 105, and the packaged circuit board 30 is provided with multiple second contact pads 306 connected to the third contact pads 105 in a one-to-one correspondence. The wiring circuit 307 includes a first wiring circuit, a second wiring circuit, and a third wiring circuit. The first wiring circuit is configured to connect the first contact pad 305 to the second contact pad 306. The second wiring circuit is configured to connect the first contact pad 305 to the second contact pad 306, and connect the first contact pad 305 and the second contact pad 306 to a corresponding first connection terminal 21. The third wiring circuit is configured to connect the first contact pad 305 or the second contact pad 306 to a corresponding first connection terminal 21.

As shown in FIG. 5, the ASIC chip 20 includes opposing front surface 202 and back surface 203. The back surface 203 of the ASIC chip 20 is disposed facing the first surface 303. The front surface 202 of the ASIC chip 20 is provided with a second function unit 204 and fourth contact pads 205 connected to the second function unit 204. The back surface 203 of the ASIC chip 20 is provided with the second connection terminals 201. Each of the second connection terminals 201 is connected to one fourth contact pad 205. The connecting the second connection terminal 201 to the first contact pad 305 includes: connecting the second connection terminal 201 to the first contact pad 305 by a welding process. In this way, the second function unit 204 is connected to the wiring circuit 307 in the packaged circuit board 30.

The back surface 203 of the ASIC chip 20 is provided with through holes 206. Each of the through holes 206 exposes one fourth contact pad 205. The back surface 203 of the ASIC chip 20 is provided with an insulation layer 207. The insulation layer 207 covers a sidewall of each of the through holes 206 and extends outside the through hole 206. A surface of the insulation layer 207 is covered with a rewiring layer 208. The rewiring layer 208 is connected to the fourth contact pad 205 at the bottom of each of the through holes 206 and extends outside the through hole 206. A surface of the rewiring layer 208 is covered with a solder mask 209. The solder mask 209 is provided with openings at a region outside the through hole 206, to expose the rewiring layer 208. Each of the second connection terminals 201 is disposed in one opening, and the second connection terminal 201 is connected to the fourth contact pad 205 via the rewiring layer 208. In an embodiment, the front surface 202 of the ASIC chip 20 is covered with a protection layer 300. The protection layer 300 covers the second function unit 204 and the fourth contact pads 205.

In an embodiment, the second connection terminal 201 is a solder bump, and the first connection terminal 21 is a solder bump. In the embodiment of the present disclosure, the solder bump may be a solder ball or a metal bump.

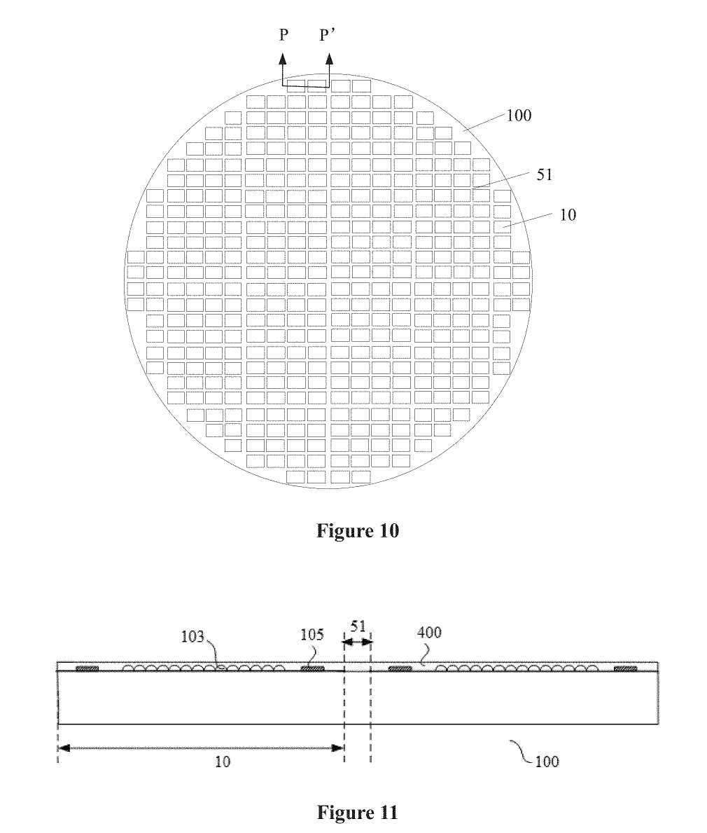

Reference is made to FIGS. 10 to 13, which are schematic diagrams showing a flowchart of a method for manufacturing a MEMS chip according to an embodiment of the present disclosure. The manufacturing method includes the following steps S21 to S23.

In step S21, as shown in FIGS. 10 and 11, a wafer 100 is provided. The wafer 100 includes multiple MEMS chips 10, and a cutting trench 51 is disposed between adjacent MEMS chips 10. FIG. 10 is a plan view of the wafer 100, and FIG. 11 is a sectional view taken along a line P-P′ in FIG. 10.

A front surface of the wafer 100 is covered with a protection layer 400. The protection layer 400 covers the first function unit 103 on the front surface of each of the MEMS chips 10. The first function unit 103 is connected to the third contact pad 105.

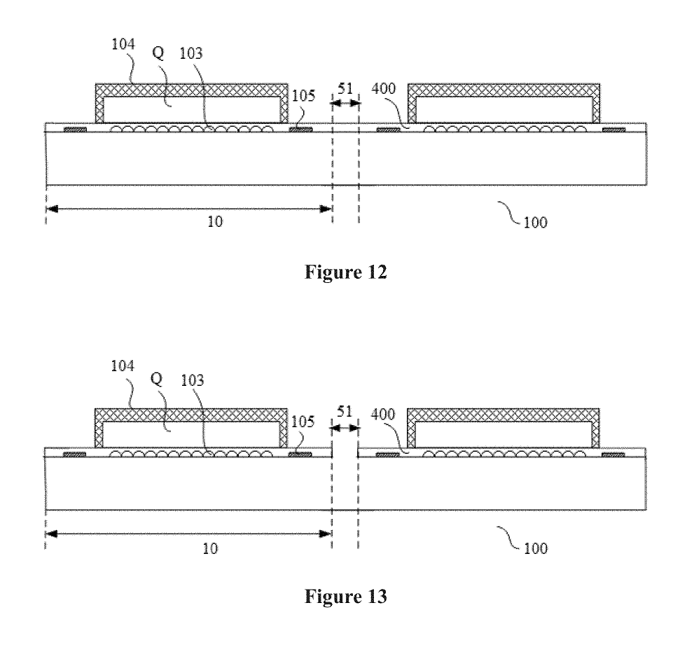

In step S22, as shown in FIG. 12, a surface of each of the MEMS chips 10 corresponding to a front surface of the wafer 100 is provided with a cover 104. The cover 104 is provided with a cavity Q.

In step S23, as shown in FIG. 13, the wafer 100 is cut along the cutting trenches 51 to form the multiple MEMS chips 10.

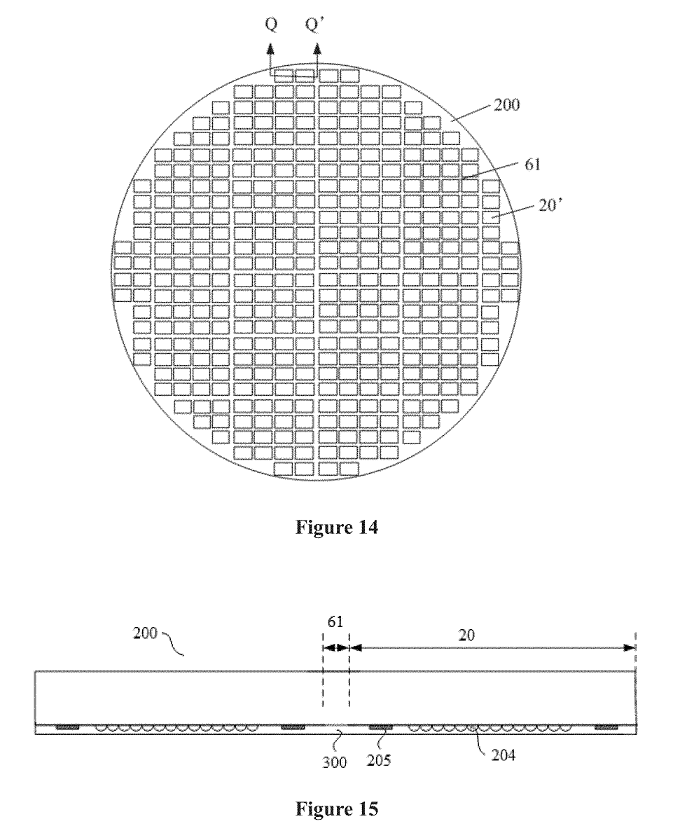

Reference is made to FIGS. 14 to 21, which are schematic diagrams showing a flowchart of a method for manufacturing an ASIC chip according to an embodiment of the present disclosure. The manufacturing method includes the following steps S31 to S37.

In step S31, as shown in FIGS. 14 and 15, a wafer 200 is provided. The wafer 200 includes multiple ASIC chips 20, and a cutting trench 61 is disposed between adjacent ASIC chips 20. FIG. 14 is a plan view of the wafer 200, and FIG. 15 is a sectional view taken along a line Q-Q′ in FIG. 14.

A front surface of the wafer 200 is covered with a protection layer 300. The protection layer 300 covers the second function unit 204 and fourth contact pads 205 on the front surface of each of the ASIC chips 20.

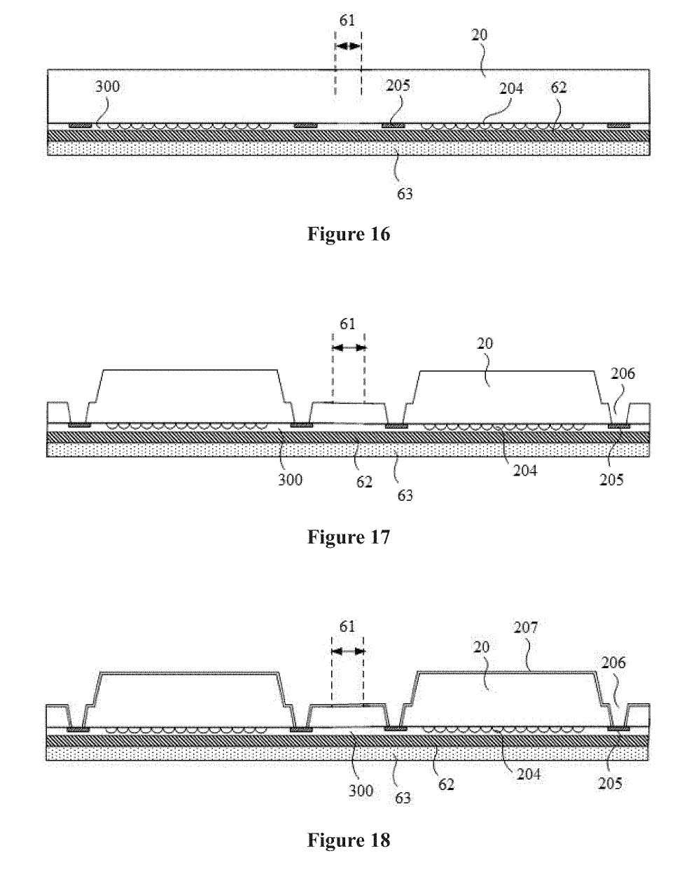

In step S32, as shown in FIG. 16, the wafer 200 is inverted and is attached on a surface of a carrier plate 63 by using an adhesive layer 62. A back surface of the wafer 200 is disposed upward.

In step S33, as shown in FIG. 17, the back surface of the wafer 200 is formed with through holes 206 to expose the fourth contact pads 205 on the front surface of each of the ASIC chips 20. Before the through holes 206 are disposed, the wafer 200 may be thinned at the back surface of the wafer 200. The through hole 206 may be a straight hole, a double-stepped through hole or a trapezoidal hole.

In step S34, as shown in FIG. 18, an insulation layer 207 is formed on the back surface of the wafer 200. The insulation layer 207 covers a sidewall of each of the through holes 206 and exposes the bottom of the through hole 206.

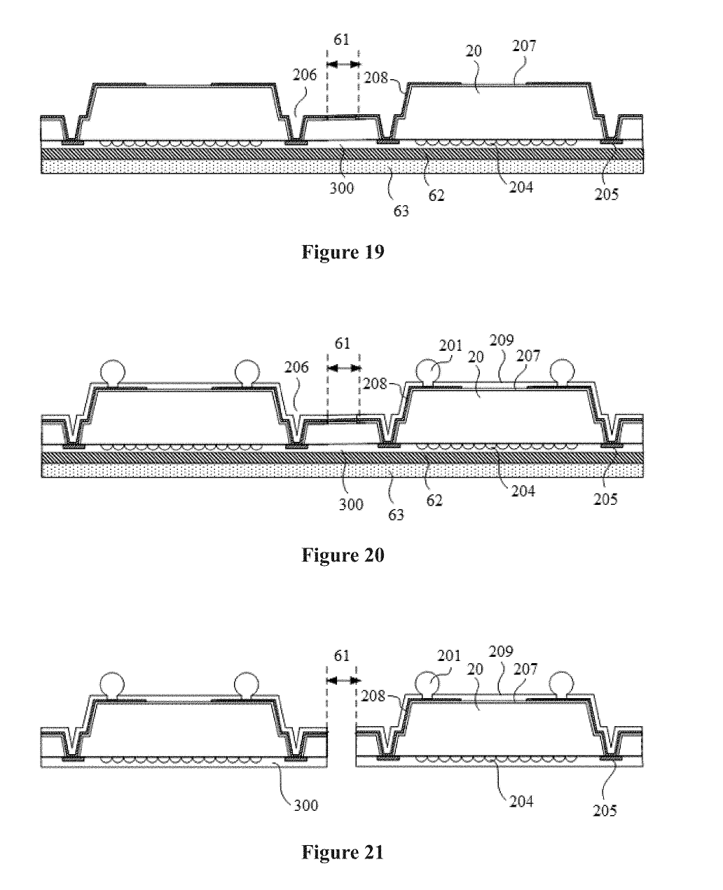

In step S35, as shown in FIG. 19, a rewiring layer 208 is formed on a surface of the insulation layer 207. The rewiring layer 208 is connected to the fourth contact pad 205 at the bottom of each of the through holes 206.

In step S36, as shown in FIG. 20, a solder mask 209 is formed on a surface of the rewiring layer 208. The solder mask 209 is provided with openings at a region outside the through holes 206.

In step S37, as shown in FIG. 21, the second connection terminal 201 is formed in the opening.

It can be seen from the above description that, the package according to the embodiment of the disclosure may be manufactured with the packaging method according to the embodiment of the present disclosure without a plastic packaging process, the manufacturing process is simple, and the manufacturing cost is low. The MEMS chip 10 and the ASIC chip 20 are packaged by using the packaged circuit board 30. The packaged circuit board 30 is provided with the receiving hole 301. The MEMS chip 10 and the ASIC chip 20 are respectively attached to two surfaces of the packaged circuit board 30 and cover the receiving hole. The MEMS chip 10 and the ASIC chip 20 are connected with each other via the packaged circuit board 30 and are connected to an external circuit via the packaged circuit board 30, thereby facilitating the circuit interconnection between the package and an electronic component.

The embodiments in this specification are described in a progressive manner, each of the embodiments emphasizes differences from other embodiments, and the same or similar parts among the embodiments can be referred to each other. For the device disclosed in the embodiments, since the device corresponds to the method disclosed in the embodiments, the description is relatively simple, and the related parts can be referred to the description of the method.

Based on the above description of the disclosed embodiments, those skilled in the art can implement or carry out the present disclosure. It is obvious for those skilled in the art to make many modifications to these embodiments. The general principle defined herein may be applied to other embodiments without departing from the spirit or scope of the present disclosure. Therefore, the present disclosure is not limited to the embodiments illustrated herein, but should be defined by the widest scope consistent with the principle and novel features disclosed herein.

1. A chip package, comprising:
a packaged circuit board provided with a receiving hole;
an application specific integrated circuit (ASIC) chip attached to one surface of the packaged circuit board and covering the receiving hole; and
a micro-electro-mechanical system (MEMS) chip attached to another surface of the packaged circuit board and covering the receiving hole, wherein the MEMS chip comprises opposing front and back surfaces, the front surface of the MEMS chip is provided with a first function unit, the front surface of the MEMS chip is disposed facing the receiving hole, and the first function unit is disposed facing the receiving hole, wherein
the packaged circuit board is provided with a wiring circuit and first connection terminals connected to the wiring circuit, each of the first connection terminals is connected with an external circuit, and the ASIC chip and the MEMS chip are connected to the wiring circuit.

2. The chip package according to claim 1, wherein the MEMS chip further comprises a cover covering the first function unit, wherein
the cover is provided with a cavity, an opening of the cavity is disposed facing the first function unit, and the cover is located in the receiving hole.

3. The chip package according to claim 2, wherein there is a gap between a top surface of the cover and the ASIC chip.

4. The chip package according to claim 1, wherein the packaged circuit board comprises opposing first and a second surfaces, the ASIC chip is attached to the first surface, and the MEMS chip is attached to the second surface.

5. The chip package according to claim 4, wherein there is a gap between the ASIC chip and the MEMS chip.

6. The chip package according to claim 4, wherein
the first surface is provided with first contact pads, the second surface is provided with second contact pads, the first contact pads and the second contact pads are connected to the wiring circuit, and the first connection terminals are located on the second surface;
a surface of the ASIC chip facing the packaged circuit board is provided with second connection terminals, and each of the second connection terminals is connected to one first contact pad; and
the front surface of the MEMS chip is provided with third contact pads connected to the first function unit, and each of the third contact pads is connected to one second contact pad.

7. The chip package according to claim 6, wherein
the ASIC chip is provided with a plurality of second connection terminals, and the packaged circuit board is provided with a plurality of first contact pads connected to the second connection terminals in a one-to-one correspondence; and
the MEMS chip is provided with a plurality of third contact pads, and the packaged circuit board is provided with a plurality of second contact pads connected to the third contact pads in a one-to-one correspondence.

8. The chip package according to claim 6, wherein the wiring circuit comprises:
a first wiring circuit configured to connect the first contact pad to the second contact pad;
a second wiring circuit configured to connect the first contact pad to the second contact pad, and connect the first contact pad and the second contact pad together to a corresponding first connection terminal, and
a third wiring circuit configured to connect the first contact pad or the second contact pad to a corresponding first connection terminal.

9. The chip package according to claim 6, wherein the ASIC chip comprises opposing front and a back surfaces, and the back surface of the ASIC chip is disposed facing the first surface, wherein
the front surface of the ASIC chip is provided with a second function unit and fourth contact pads connected to the second function unit; and
the back surface of the ASIC chip is provided with the second connection terminals, and each of the second connection terminals is connected to one fourth contact pad.

10. The chip package according to claim 9, wherein
the back surface of the ASIC chip is provided with through holes, and each of the through holes exposes one fourth contact pad;
the back surface of the ASIC chip is provided with an insulation layer, and the insulation layer covers a sidewall of each of the through holes and extends outside the through hole;
a surface of the insulation layer is covered with a rewiring layer, and the rewiring layer is connected to the fourth contact pad at the bottom of each of the through holes and extends outside the through hole; and
a surface of the rewiring layer is covered with a solder mask, the solder mask has openings at a region outside the through holes for exposing the rewiring layer, and each of the second connection terminals is disposed in one opening, and the second connection terminal is connected to the fourth contact pad via the rewiring layer.

11. A chip packaging method, comprising:
providing a to-be-cut substrate, wherein the to-be-cut substrate comprises a plurality of chip attaching regions, a cutting trench is formed between adjacent chip attaching regions, each of the chip attaching regions is provided with a wiring circuit and a receiving hole penetrating the to-be-cut substrate;
attaching an application specific integrated circuit (ASIC) chip to one surface of the chip attaching region and attaching a micro-electro-mechanical system (MEMS) chip to another surface of the chip attaching region, wherein the ASIC chip and the MEMS chip cover the receiving hole, the MEMS chip comprises opposing front and a back surfaces, the front surface of the MEMS chip is provided with a first function unit, the front surface of the MEMS chip is disposed facing the receiving hole, the first function unit is disposed facing the receiving hole, and the ASIC chip and the MEMS chip are connected to the wiring circuit;
forming first connection terminals connected to the wiring circuit on a surface of the chip attaching region to which the MEMS chip is attached, wherein each of the first connection terminals is connected to an external circuit; and
cutting the to-be-cut substrate along the cutting trenches to form a plurality of packaged circuit boards, wherein each of the packaged circuit boards comprises one chip attaching region, and each of the packaged circuit boards is attached with one ASIC chip and one MEMS chip.

12. The chip packaging method according to claim 11, wherein the MEMS chip further comprises a cover covering the first function unit, wherein
the cover is provided with a cavity, an opening of the cavity is disposed facing the first function unit, and the cover is located in the receiving hole.

13. The chip packaging method according to claim 12, wherein there is a gap between a top surface of the cover and the ASIC chip.

14. The chip packaging method according to claim 11, wherein the packaged circuit board comprises opposing first and a second surfaces, the ASIC chip is attached to the first surface, and the MEMS chip is attached to the second surface.

15. The chip packaging method according to claim 14, wherein there is a gap between the ASIC chip and the MEMS chip.

16. The chip packaging method according to claim 14, wherein
the first surface is provided with first contact pads, the second surface is provided with second contact pads, the first contact pads and the second contact pads are connected to the wiring circuit, and the first connection terminals are located on the second surface;
a surface of the ASIC chip facing the packaged circuit board is provided with second connection terminals, and the front surface of the MEMS chip is provided with third contact pads connected to the first function unit; and
the attaching the ASIC chip to one surface of the chip attaching region and attaching the MEMS chip to another surface of the chip attaching region comprises: connecting the second connection terminal to the first contact pad, and connecting the third contact pad to the second contact pad.

17. The chip packaging method according to claim 16, wherein
the ASIC chip is provided with a plurality of second connection terminals, and the packaged circuit board is provided with a plurality of first contact pads connected to the second connection terminals in a one-to-one correspondence; and
the MEMS chip is provided with a plurality of third contact pads, and the packaged circuit board is provided with a plurality of second contact pads connected to the third contact pads in a one-to-one correspondence.

18. The chip packaging method according to claim 16, wherein the wiring circuit comprises:
a first wiring circuit configured to connect the first contact pad to the second contact pad;
a second wiring circuit configured to connect the first contact pad to the second contact pad, and connect the first contact pad and the second contact pad together to a corresponding first connection terminal; and
a third wiring circuit configured to connect the first contact pad or the second contact pad to a corresponding first connection terminal.

19. The chip packaging method according to claim 16, wherein the ASIC chip comprises opposing front and a back surfaces, and the back surface of the ASIC chip is disposed facing the first surface, wherein
the front surface of the ASIC chip is provided with a second function unit and fourth contact pads connected to the second function unit, the back surface of the ASIC chip is provided with the second connection terminals, and each of the second connection terminals is connected to one fourth contact pad, and
the connecting the second connection terminal to the first contact pad comprises: connecting the second connection terminal to the first contact pad by a welding process.

20. The chip packaging method according to claim 19, wherein
the back surface of the ASIC chip is provided with through holes, and each of the through holes exposes one fourth contact pad;
the back surface of the ASIC chip is provided with an insulation layer, and the insulation layer covers a sidewall of each of the through holes and extends outside the through hole;
a surface of the insulation layer is covered with a rewiring layer, and the rewiring layer is connected to the fourth contact pad at the bottom of each of the through holes and extends outside the through hole; and
a surface of the rewiring layer is covered with a solder mask, the solder mask is provided with openings at a region outside the through holes for exposing the rewiring layer, and each of the second connection terminals is disposed in one opening, and the second connection terminal is connected to the fourth contact pad via the rewiring layer.
